(19) United States
(12) Patent Application Publication
(10) Pub. No.: US 2026/0310100 A1
(43) Pub. Date: Oct. 8, 2026

(54) METHODS AND APPARATUSES FOR OBTAINING A CALIBRATION FOR A SUBSTRATE TOPOGRAPHY MEASUREMENT AND METHODS AND APPARATUSES FOR DETERMINING A TOPOGRAPHY OF A SUBSTRATE USING THE CALIBRATION

(71) Applicant: ASML Netherlands B.V., Veldhoven (NL)

(72) Inventors: Abraham Franciscus Hubertus VAN GESSEL, Waalre (NL); Arend Johannes DONKERBROEK, Aarle-Rixtel (NL); Attaallah ALMASI, Utrecht (NL)

(73) Assignee: ASML Netherlands B.V., Veldhoven (NL)

(21) Appl. No.: 19/481,468

(22) PCT Filed: May 23, 2024
(86) PCT No.: PCT/EP2024/064236

§ 371 Date: Nov. 4, 2025

(30) Foreign Application Priority Data
Jun. 1, 2023 (EP) 23176751.8

(51) Int. Cl. G03F 7/00; G01B 11/30

(52) U.S. Cl. CPC G03F 7/70516; G01B 11/303; G03F 7/70525; G03F 7/70775; G03F 7/7085

(57) ABSTRACT

A method of obtaining a calibration for a substrate topography measurement, the method comprising: for each of a plurality of locations on a calibration substrate: obtaining a calibration substrate height reference value at the location; and obtaining a plurality of calibration substrate height measurement values at the location, each calibration substrate height measurement value corresponding to a measurement of a surface of the calibration substrate at the location, wherein a total number of the plurality of locations is greater than a total number of the plurality of calibration substrate height measurement values obtained at each location; the method further comprising: using the plurality of calibration substrate height measurement values obtained for each location, and the calibration substrate height reference values obtained for each location, to determine a plurality of calibration terms for the calibration substrate height measurement values.

### CROSS-REFERENCE TO RELATED APPLICATION

The application claims priority of EP application 23176751.8 which was filed on 1 Jun. 2023 and which is incorporated herein in its entirety by reference.

### FIELD

The present disclosure relates to methods and apparatuses for obtaining a calibration for a substrate topography measurement, and to methods and apparatuses for determining a topography of a substrate using the calibration.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask also referred to as a reticle) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Typically, the substrate may include multiple layers comprising one or more materials (each layer having been patterned by a reticle) and each of the layers may comprise multiple repetitions of the same pattern. The patterns of each layer may be arranged as a two-dimensional array. Any and all references to “substrate” are to be understood as comprising a ‘base’ substrate, e.g. a silicon or glass substrate, or any other appropriate base substrate, and any layers provided thereupon, including but not limited to previously exposed and processed patterned layers, and/or photoresist.

Different points across a surface of the substrate may be at different heights, and so lithographic radiation focused on the surface of the substrate at a first point (at a first height) may not be in focus at a second point (at a second height). To maintain focus on the substrate surface, the height of the surface of the substrate is measured and corresponding adjustments of the lithographic apparatus are made.

The height of the surface of the substrate may be measured using a height measurement system. However, it is known that light which is used by a height measurement system to measure the height of the surface of the substrate may penetrate partially into the substrate surface, instead of being reflected solely from the substrate surface. A partial reflection of the light may occur from layers beneath the surface of the substrate. This partial reflection causes a substrate height measurement error.

The substrate height measurement error may be referred to as height process dependency (HPD) or apparent surface depression (ASD).

It may be desirable to provide a system that obviates or mitigates one or more problems associated with the prior art.

### SUMMARY

As mentioned above, to maintain focus on a substrate surface, the height across the surface of the substrate, referred to herein as the topography of the substrate, is measured. The height measurement error at a given location on the substrate surface (e.g. the height process dependency, HPD) may be reduced by optimizing the optical properties of the height measurement system (e.g. the spectrum of the light used for the measurement, the angle of incidence, the focus, etc.). However, these techniques become increasingly technically difficult as the system is optimized further. In addition, it is important to provide a solution for reducing the height measurement error that is universally applicable to any substrate.

The present disclosure therefore provides methods and apparatuses for determining a calibration for a substrate topography measurement. The calibration, which may be determined using a physical calibration substrate, and/or a simulated calibration substrate, can then be used to adjust a topography measurement of a production substrate to reduce or remove the deviation of the measurement from the real value due to the height measurement error.

As used herein, the term “calibration substrate” may refer to a substrate that is used for the purposes of obtaining the calibration, and the term “production substrate” may refer to a substrate the topography of which is to be determined using the calibration, for example as part of an IC manufacturing process. For example, the production substrate may refer to one of a large number of production substrates within a mass production process. However, it will be understood that this terminology is generally arbitrary and serves merely to differentiate the substrates referred to in the methods and apparatuses described and claimed herein.

According to the present disclosure, there is provided a method of obtaining a calibration for a substrate topography measurement, the method comprising: for each of a plurality of locations on a calibration substrate: obtaining a calibration substrate height reference value at the location; and obtaining a plurality of calibration substrate height measurement values at the location, each calibration substrate height measurement value corresponding to a measurement of a surface of the calibration substrate at the location. A total number of the plurality of locations may be greater than a total number of the plurality of calibration substrate height measurement values obtained at each location. The method may further comprise using the plurality of calibration substrate height measurement values obtained for each location, and the calibration substrate height reference values obtained for each location, to determine a plurality of calibration terms for the calibration substrate height measurement values.

Advantageously, the calibration method described herein may be carried out in respect of any substrate, the topography of which is to be determined, and may only need to be carried out once for a given type of production substrate. Further advantageously, unlike some known methods to remove the error from the height measurements themselves, the calibration method described herein is not limited by the physical limits of a system used to determine the calibration and/or a substrate topography.

The calibration substrate height reference values may be obtained by any suitable method to give a measurement of the calibration substrate topography that can be assumed for the purposes of the methods described herein to be substantially the same as the true topography of the calibration substrate. In applications where the calibration substrate height reference values are obtained by measurement of the height of a physical calibration substrate at several locations on the calibration substrate, such a measurement may be slow and therefore unsuitable for a mass production process. The methods described herein may therefore enable all of the topography measurements of the production substrates in a manufacturing process to benefit from the precise measurement of the calibration substrate topography while also enabling a high throughput of process substrates since the height reference values only need to be obtained once (on the calibration substrate) and do not need to be obtained for each of the process substrates.

Similarly to applications in which a physical calibration substrate is employed, applications where the calibration substrate height reference values are obtained by simulation (i.e. based on a simulated calibration substrate), also enable a high throughput of process substrates because only one substrate (the calibration substrate) needs to be simulated to obtain the calibration terms.

The plurality of calibration terms may be determined by means of multi variable regression.

The plurality of calibration substrate height measurement values may comprise one or more values corresponding to an intensity measurement. For example, one or more calibration substrate height measurement values may correspond to an intensity of a beam of radiation reflected by the calibration substrate. In some examples, the reflected radiation may be separated into portions, and one or more of the calibration substrate height measurement values may correspond to intensities of one or more portions. In some examples, one of more of the calibration substrate height measurement values may correspond to a total of intensities of one or more portions.

The plurality of calibration substrate height measurement values may comprise one or more values corresponding to a polarization filtered measurement. For example, one or more beams of radiation, or portions of beams of radiation, reflected by the calibration substrate may pass through one or more polarization filters before being detected. In some examples, several calibration substrate height measurement values may be obtained corresponding to a reflected beam of radiation at several different polarizations.

The plurality of calibration substrate height measurement values may comprise one or more values corresponding to measurements obtained at different measurement wavelengths. For example, one or more beams of radiation may be incident on the calibration substrate, and one or more calibration substrate height measurement values may correspond to intensities of radiation at different wavelengths reflected by the calibration substrate. In some examples, the beam of radiation incident on the calibration substrate may comprise broadband radiation. The measurement wavelengths may comprise measurements of the beam of radiation following reflection by the calibration substrate and filtering to select specific wavelengths. In some examples, multiple beams of radiation each having different single wavelengths (e.g. originating from one or more lasers) may be incident on the calibration substrate, and the intensities of the multiple beams of radiation at different wavelengths may be detected following reflection by the calibration substrate.

The plurality of calibration substrate height measurement values may comprise values corresponding to measurements obtained using modulated radiation, e.g. wavelength modulated radiation. For example, obtaining a measurement using modulated radiation may comprise directing a wavelength modulated beam of radiation (e.g. a wavelength modulated laser beam), having a wavelength that is modulated at a given frequency, onto the calibration substrate at a location on the calibration substrate, and detecting a position of the wavelength modulated beam of radiation at the location after it has been reflected from the calibration substrate, using detection based upon the frequency of the modulation applied to the wavelength of the beam of radiation to measure modulation of the detected position of the wavelength modulated beam of radiation.

Detecting the modulation of the detected position of the wavelength modulated beam of radiation may comprise using a harmonic of the frequency of the modulation applied to the wavelength of the beam of radiation.

The detection may be lock-in detection which automatically selects between a first harmonic, second harmonic, or other harmonic of the frequency of the modulation based upon amplitudes of those harmonics.

The modulation of the wavelength of the beam of radiation may be up to 1/100th of the wavelength of the beam of radiation.

The modulation of the wavelength of the beam of radiation may be up to 100 pm.

The beam of radiation may be provided by a single frequency laser.

One or more of the calibration substrate height reference values may be simulated calibration substrate height reference values. For example, a simulated calibration substrate may be used to determine one or more of the calibration substrate height reference values.

One or more of the calibration substrate height reference values may be obtained by measurement of the calibration substrate at the location (i.e. by physical measurement of a physical calibration substrate). For example, one or more of the calibration substrate height reference values may be determined using an air gauge measurement, a focus exposure matrix measurement, a microscopy (e.g. atomic force microscopy, scanning probe microscopy, and/or scanning tunneling microscopy) measurement, or the like. Advantageously, obtaining the calibration substrate height reference values (and/or the calibration substrate height measurement values) by measurement of a physical substrate enables the use of the method described herein to calibrate a substrate topography measurement for any substrate, without prior knowledge of the properties of the substrate.

One or more of the calibration substrate height measurement values may be simulated calibration substrate height measurement values. For example, a simulated calibration substrate may be used to determine one or more of the calibration substrate height measurement values. In some examples, the simulated calibration substrate height measurement values may be determined based on the calibration substrate height reference values, where the calibration substrate height reference values may be simulated and/or determined from measurement of a physical calibration substrate, as described herein. Simulated calibration substrate height measurement values may be determined from simulations of any of the measurement techniques for obtaining calibration substrate height measurement values described herein.

One or more of the calibration substrate height measurement values may be obtained by a measurement of the calibration substrate at the location. For example, one or more of the calibration substrate height measurement values may be obtained by measurement of a physical calibration substrate according to one or more of the methods for obtaining calibration substrate height measurement values described herein.

Additionally according to the present disclosure, there is provided a method of determining a topography of a production substrate, the method comprising: obtaining a plurality of production substrate height measurement values at a plurality of locations on a production substrate, each production substrate height measurement value corresponding to a measurement of a surface of the production substrate at a respective location of the plurality of locations on the production substrate. The method may further comprise: receiving a set of calibration terms obtained by a method described herein; and adjusting the production substrate height measurement values based on the calibration terms.

Advantageously, in the present method of determining the topography of a production substrate, a single calibration (i.e. set of calibration terms obtained for a calibration substrate) can be applied to all production substrates of a same type. Further advantageously, unlike some known methods to remove the error from the height measurements themselves, applying the calibration as described herein means that the removal (or correction) of the height measurement error is not limited by the physical limits of a system used to determine the calibration and/or the substrate topography.

The production substrate height measurement values may be obtained using one or more of the methods described herein in relation to obtaining calibration substrate height measurement values, so that a set of production substrate height measurement values corresponding to the calibration substrate height measurement values is obtained.

Further according to the present disclosure, there is provided an apparatus for obtaining a calibration for a substrate topography measurement. The apparatus may comprise: a support for supporting a calibration substrate; a projection unit configured to direct a beam of radiation onto a location on the calibration substrate; a movement mechanism operable to adjust the support and/or the projection unit so as to move the location on the calibration substrate at which the beam of radiation is directed onto the calibration substrate; a detection system configured to detect the radiation after reflection by the calibration substrate, the detection system further configured to determine a calibration substrate height measurement value corresponding to a measurement of a surface of the calibration substrate at the location; and one or more controllers configured to operate the movement mechanism such that the beam of radiation is incident on a plurality of locations on the calibration substrate.

The one or more controllers may be further configured, for each of the plurality of locations on the calibration substrate, to: receive a calibration substrate height reference value at the location; and receive a plurality of calibration substrate height measurement values from the detection system, wherein a total number of the plurality of locations is greater than a total number of the plurality of calibration substrate height measurement values received at each location. The one or more controllers may be further configured to determine a plurality of calibration terms for the calibration substrate height measurement values using the plurality of calibration substrate height measurement values received for each location, and the calibration substrate height reference values received for each location.

Advantageously, the apparatus described herein can be used to obtain a calibration for any kind of substrate, without requiring prior knowledge of the properties of the substrate. Further advantageously, the calibration only needs to be performed once for a given type of production substrate. The apparatus described herein may therefore enable all of the topography measurements of the production substrates in a manufacturing process to benefit from the precise measurement of the calibration substrate topography while also enabling a high throughput of process substrates since the height reference values only need to be obtained once (on the calibration substrate) and do not need to be obtained for each of the process substrates.

In addition, calibrating a substrate topography measurement using the apparatus described herein is not limited by the physical limits of the projection and detection systems, or by the projection and detection systems of an apparatus used for determining the topography of a production substrate.

As described above, one or more of the calibration substrate height reference values may be obtained by measurement of the calibration substrate at the location (i.e. by physical measurement of a physical calibration substrate). For example, one or more of the calibration substrate height reference values may be determined using an air gauge measurement, a focus exposure matrix measurement, a microscopy (e.g. atomic force microscopy, scanning probe microscopy, and/or scanning tunneling microscopy) measurement, or the like, or by simulation. In some examples, the calibration substrate height reference values may be determined using the apparatus for obtaining the calibration for the substrate topography measurement described herein, but in other examples the calibration substrate height reference values may be obtained by other means.

The controller may be configured to determine the plurality of calibration terms by means of multiple variable regression.

The detection system may be configured to determine one or more calibration substrate height measurement values corresponding to an intensity measurement. For example, one or more calibration substrate height measurement values may correspond to an intensity of the beam of radiation reflected by the calibration substrate. In some examples, the reflected radiation may be separated into portions (e.g. using appropriate optical elements such as mirrors, filters, gratings, and the like), and one or more of the calibration substrate height measurement values may correspond to intensities of one or more portions. In some examples, one of more of the calibration substrate height measurement values may correspond to a total of intensities of one or more portions.

The detection system may be configured to determine one or more calibration substrate height measurement values corresponding to a polarization filtered measurement. For example, the apparatus may comprise one or more polarization filters, and the beam of radiation reflected by the calibration substrate may pass through one or more polarization filters before being detected by the detection system. In some examples, the detection system may be configured to obtain several calibration substrate height measurement values corresponding to a reflected beam of radiation at several different polarizations, e.g. using several different polarization filters.

The detection system may be configured to determine one or more calibration substrate height measurement values corresponding to measurements obtained at different measurement wavelengths. For example, one or more calibration substrate height measurement values may correspond to intensities of radiation at different wavelengths reflected by the calibration substrate and detected by the detection system. In some examples, the projection unit may be configured to direct a beam of radiation comprising broadband radiation onto the calibration substrate. The measurement wavelengths may comprise measurements of the beam of radiation following reflection by the calibration substrate and filtering to select specific wavelengths. For example, the apparatus may comprise one or more narrow bandpass filters, and/or diffraction gratings or prisms to enable wavelength selection from a broadband radiation source. In some examples, the projection unit may be configured to direct multiple beams of radiation each having different single wavelengths (e.g. originating from one or more lasers) onto the calibration substrate, and the detection system may be configured to detect the intensities of the multiple beams of radiation at different wavelengths following reflection by the calibration substrate.

The detection system may be configured to determine one or more calibration substrate height measurement values corresponding to measurements obtained using modulated radiation, e.g. wavelength modulated radiation. For example, the projection unit may be configured to direct a wavelength modulated beam of radiation (e.g. a wavelength modulated laser beam), having a wavelength that is modulated at a given frequency, onto the calibration substrate at a location on the calibration substrate, and the detection system may be configured to detect a position of the wavelength modulated beam of radiation at the location after it has been reflected from the calibration substrate, using detection based upon the frequency of the modulation applied to the wavelength of the beam of radiation to measure modulation of the detected position of the wavelength modulated beam of radiation.

The detection system may be configured to detect the modulation of the detected position of the wavelength modulated beam of radiation using a harmonic of the frequency of the modulation applied to the wavelength of the beam of radiation.

The detection system may be configured to detect the radiation using lock-in detection which automatically selects between a first harmonic, second harmonic, or other harmonic of the frequency of the modulation based upon amplitudes of those harmonics. For example, the detection system may comprise a lock-in amplifier.

The wavelength of the beam of radiation may modulated by up to 1/100th of the wavelength of the beam of radiation.

The wavelength of the beam of radiation may be modulated by up to 100 pm.

The beam of radiation may be provided by a single frequency laser.

Additionally according to the present disclosure, there is provided an apparatus for determining a topography of a production substrate. The apparatus may comprise: a support for supporting a production substrate; a projection unit configured to direct a beam of radiation onto a location on the production substrate; a movement mechanism operable to adjust the support and/or the projection unit so as to move the location on the production substrate at which the beam of radiation is directed onto the production substrate; a detection system configured to detect the radiation after reflection by the location on the production substrate, the detection system further configured to determine a production substrate height measurement value corresponding to a height of the production substrate at the location; and one or more controllers configured to operate the movement mechanism such that the beam of radiation is incident on a plurality of locations on the production substrate.

The one or more controllers may be further configured, for each of the plurality of locations on the production substrate, to: receive a plurality of production substrate height measurement values from the detection system; receive a set of calibration terms; and adjust the production substrate height measurement values based on the calibration terms. The calibration terms received by the one or more controllers may be obtained by a method as described herein. The calibration terms received by the one or more controllers may be obtained using the apparatus for obtaining a calibration for a substrate topography measurement described herein.

Advantageously, the apparatus for determining a topography of a production substrate described herein enables a single calibration (i.e. set of calibration terms obtained for a calibration substrate) to be applied to all production substrates of a same type. Further advantageously, the removal (or correction) of the height measurement error is not limited by the physical limits of the apparatus.

In some examples, the apparatus for obtaining a calibration for a substrate topography measurement may form part of an apparatus for determining a topography of a production substrate.

In general, it will be understood that the terms “calibration substrate height measurement values” and “production substrate height measurement values” as used herein may refer to values corresponding to measurements of the calibration and production substrates, respectively. The measurements of the calibration and/or production substrates may comprise, for example, direct measurements of a substrate height (i.e. at a location), measurements of a height measurement error, and/or intensity measurements or other types of measurements containing information relating to the height of the substrate.

The locations on the production substrate(s) on which the production substrate height measurement values are obtained should correspond (e.g. be the same or substantially the same) as the locations on the respective calibration substrate at which the calibration substrate height measurement values and calibration substrate height reference values are obtained.

### BRIEF DESCRIPTION OF THE DRAWINGS

Embodiments of the disclosure will now be described, by way of example only, with reference to the accompanying drawings, in which:

FIG. 1 schematically depicts a lithographic apparatus which includes a system for determining a substrate height measurement error according to the present disclosure;

FIG. 2 schematically depicts an example of a height measurement system and/or a height measurement calibration system according to the present disclosure;

FIG. 3 schematically depicts in more detail an example of a height measurement calibration system according to the present disclosure;

FIG. 4 schematically depicts a method for obtaining a calibration for a substrate topography measurement according to the present disclosure;

FIG. 5 schematically depicts a method for obtaining a topography of a production substrate according to the present disclosure;

FIGS. 6(a)-(c) illustrate simulated substrate height measurement values obtained for a simulated substrate; and

FIGS. 7(a) and (b) illustrate a height measurement error across a set of simulated substrates obtained using different total numbers of substrate height measurement values.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate.

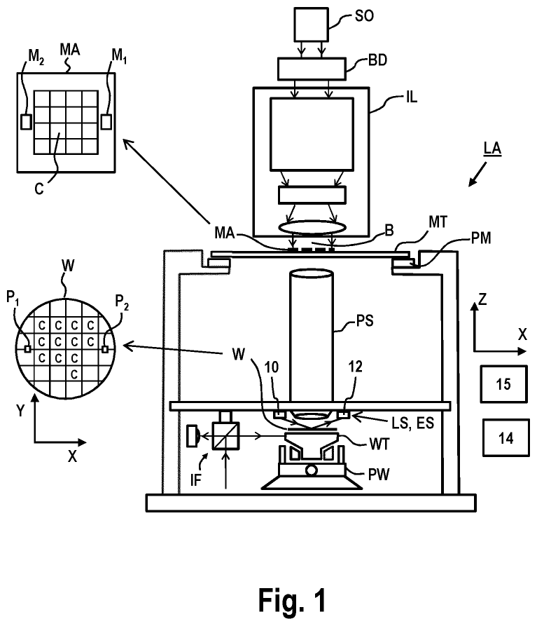

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT. In such a “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the disclosure, a Cartesian coordinate system is used. The Cartesian coordinate system has three axes, i.e., an x-axis, a y-axis and a z-axis. Each of the three axes is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the disclosure and is used for clarification only. Instead, another coordinate system, such as a cylindrical coordinate system, may be used to clarify the disclosure. The orientation of the Cartesian coordinate system may be different, for example, such that the z-axis has a component along the horizontal plane. In the figures, the height of the substrate W is indicated as the Z-direction.

A height measurement system LS is arranged to measure a topography of a top surface of the substrate W. The height measurement system LS may be referred to as a level sensor, or a topography measurement system. A map of the height (z) of the substrate as a function of position (x, y) on the substrate may be generated from measurements obtained using the height measurement system LS. This height map may subsequently be used to adjust the vertical position of the substrate W, and/or to adjust the projection system PS, during projection of a pattern from the patterning device MA onto the substrate.

The height measurement system LS may be stationary. The substrate table WT and substrate W may be moved in a scanning movement beneath the height measurement system LS. This allows the height measurement system to measure height across a surface of the substrate W and thereby generate a height map.

The height measurement system LS comprises a projection unit 10, a detection system 12, and a processor 15. The projection unit 10 is configured to provide a beam of light which is incident upon the substrate W (including any patterned layers thereon) and is then detected by the detection system 12. A position at which the beam of light is incident at the detection system 12 depends upon the height of the substrate W. This allows the height of the substrate W to be measured. The projection unit 10 comprises a diffraction grating (not depicted) which may be referred to as a projection grating. The detection system 12 comprises a diffraction grating (not depicted) which may be referred to as a detection grating. An image of the projection grating is formed at the diffraction grating, and a position of this grating image relative to the detection grating provides the height measurement.

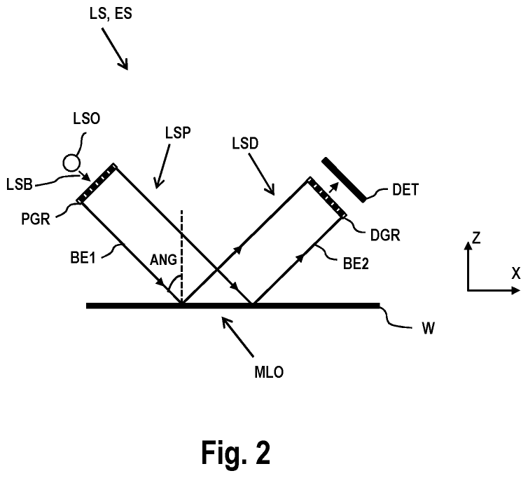

The height measurement system LS may comprise multiple lasers (or other light sources). The height measurement system LS may for example comprise a broadband light source, for example a white light source which emits light across the visible spectrum. The height measurement system may for example comprise a multiple lasers which are configured to emit light at different wavelengths. An output from the detection system 12 may be processed by the processor 15 to obtain a measured height of the substrate W. The measured height of the substrate may include a height measurement error. The height measurement error may arise from the reflection of light from multiple layers of the substrate (as explained further below in connection with FIG. 2). The height measurement error may be referred to as height process dependency (HPD).

The height measurement error, HPD(x), at a given location, x, on the substrate W during production may be defined as:

$$HPD ( x ) = LS ( x ) - TOPO ( x ) \qquad ( 1 )$$

where LS(x) is the height measurement value obtained by the height measurement system LS at location x on the substrate, and TOPO(x) is the real substrate topology, or height, at location x.

During a measurement of a substrate topography (also referred to as a substrate, or wafer, map measurement), multiple values S₁ (x), S₂(x), . . . , Sₙ(x) corresponding to measurements (or signals) from the height measurement system LS may be obtained (e.g. simultaneously) at each location x on the substrate. For example, these values may correspond to an intensity of radiation reflected by the substrate, polarization filtered measurements, measurements obtained at different wavelengths, measurements obtained using modulated radiation, and/or any other kind of filtered measurement of the substrate height.

The inventors have found that HPD(x) can be approximated by a linear combination of these values:

$$HPD ( x ) = {C}_{0} + {C}_{1} {S}_{1} ( x ) + {C}_{2} {S}_{2} ( x ) + … + {C}_{n} {S}_{n} ( x ) \qquad ( 2 )$$

where [C₀, C₁, C₂, . . . , Cₙ] is a set of calibration terms to be determined using a reference height measurement, REF(x). REF(x) may be determined by any suitable method for determining a topography of a substrate. It will be understood that REF(x) may be determined by a method that would be unsuitable to be performed on many production substrates, for example a method that would be too slow or inefficient for a mass production process. However, according to the present disclosure, REF(x) may need only to be obtained once for a calibration substrate, and so the resulting benefit of improved ability to correct for HPD may therefore provide an acceptable trade off in terms of time and resources. REF(x) may be determined, for example, from an air gauge measurement, a focus exposure matrix measurement, a microscopy (e.g. scanning tunneling microscopy) measurement, or the like. In some examples, REF(x) may be determined by simulation. It is further proposed that in the linear combination of signals, principal-component analysis could be used to have a stronger fit, suppress potential noise and retrieve more information.

It is assumed that REF(x) is a good approximation for TOPO(x) such that:

$$HPD ( x ) = LS ( x ) - REF ( x ) \qquad ( 3 )$$

A plurality of height measurements at a plurality of locations x₁, x₂, . . . , xₘ on a substrate (i.e. a substrate topography measurement) can be determined. In matrix formulation:

$$C * S = LS - REF \qquad ( 4 )$$

$$where :$$

$$REF = [ \begin{matrix}REF ( {x}_{1} ) \\ REF ( {x}_{2} ) \\ ⋮ \\ REF ( {x}_{m} )\end{matrix} ] ,$$

$$TOPO = [ \begin{matrix}TOPO ( {x}_{1} ) \\ TOPO ( {x}_{2} ) \\ ⋮ \\ TOPO ( {x}_{m} )\end{matrix} ] ,$$

$$LS = [ \begin{matrix}LS ( {x}_{1} ) \\ LS ( {x}_{2} ) \\ ⋮ \\ LS ( {x}_{m} )\end{matrix} ] ,$$

$$S = [ \begin{matrix}1 & {S}_{1} ( {x}_{1} ) & … & {S}_{n} ( {x}_{1} ) \\ 1 & {S}_{1} ( {x}_{2} ) & … & {S}_{n} ( {x}_{2} ) \\ ⋮ & ⋮ & ⋱ & ⋮ \\ 1 & {S}_{1} ( {x}_{m} ) & … & {S}_{n} ( {x}_{m} )\end{matrix} ] ,$$

$$C = [ \begin{matrix}{C}_{0} \\ {C}_{1} \\ ⋮ \\ {C}_{n}\end{matrix} ] .$$

The calibration terms C are obtained once for a given type of substrate, for example by simulation and/or based on height measurements of a physical calibration substrate. For example, the lithographic apparatus illustrated in FIG. 1 may further comprise a height measurement calibration system ES. The height measurement calibration system ES uses some of the same components as the height measurement system LS, and these are indicated as common components in FIG. 1.

The height measurement calibration system ES comprises a light source configured to produce a beam of radiation. For example, the light source may be a single frequency laser. The single frequency laser may for example have a bandwidth of 10 MHz or less, e.g. a bandwidth of around 1 MHz. The light source may form part of the projection unit 10. A position of a reflection of the laser beam is detected by the detection system 12.

The calibration terms C may be updated at given intervals based for example on obtained reference height measurement data. Advantageously, updating the calibration terms in this way can keep track of process changes.

An example of a level or height sensor LS as known in the art is schematically shown in FIG. 2, which illustrates only the principles of operation. The level or height sensor LS may also share several components with the height measurement calibration system ES as described herein. In the example illustrated in FIG. 2, the level sensor comprises an optical system, which includes a projection unit LSP and a detection unit LSD. The projection unit LSP comprises a radiation source LSO (also referred to herein as a light source) providing a beam of radiation LSB which is imparted by a projection grating PGR of the projection unit LSP. The radiation source LSO may be, for example, a narrowband or broadband radiation source, such as a supercontinuum light source, polarized or non-polarized, pulsed or continuous, such as a polarized or non-polarized laser beam. The radiation source LSO may include a plurality of radiation sources having different colors, or wavelength ranges, such as a plurality of LEDs. The radiation source LSO of the level sensor LS is not restricted to visible radiation, but may additionally or alternatively encompass UV and/or IR radiation and any range of wavelengths suitable to reflect from a surface of a substrate.

The projection grating PGR is a periodic grating comprising a periodic structure resulting in a beam of radiation BE1 having a periodically varying intensity. The beam of radiation BE1 with the periodically varying intensity is directed towards a measurement location MLO on a substrate W having an angle of incidence ANG with respect to an axis perpendicular (Z-axis) to the incident substrate surface between 0 degrees and 90 degrees, typically between 70 degrees and 80 degrees. At the measurement location MLO, the patterned beam of radiation BE1 is reflected by the substrate W (indicated by arrows BE2) and directed towards the detection unit LSD.

In order to determine the height level at the measurement location MLO, the level sensor further comprises a detection system comprising a detection grating DGR, a detector DET and a processing unit (not shown) for processing an output signal of the detector DET. The detection grating DGR may be identical to the projection grating PGR. The detector DET produces a detector output signal indicative of the light received, for example indicative of the intensity of the light received, such as a photodetector, or representative of a spatial distribution of the intensity received, such as a camera. The detector DET may comprise any combination of one or more detector types.

By means of triangulation techniques, the height level at the measurement location MLO can be determined. The detected height level is typically related to the signal strength as measured by the detector DET, the signal strength having a periodicity that depends, amongst others, on the design of the projection grating PGR and the (oblique) angle of incidence ANG.

The projection unit LSP and/or the detection unit LSD may include further optical elements, such as lenses and/or mirrors, along the path of the patterned beam of radiation between the projection grating PGR and the detection grating DGR (not shown).

In an embodiment, the detection grating DGR may be omitted, and the detector DET may be placed at the position where the detection grating DGR is located. Such a configuration provides a more direct detection of the image of the projection grating PGR.

In order to cover the surface of the substrate W effectively, a level sensor LS may be configured to project an array of measurement beams BE1 onto the surface of the substrate W, thereby generating an array of measurement areas MLO or spots covering a larger measurement range.

Various height sensors of a general type are disclosed for example in U.S. Pat. Nos. 7,265,364 and 7,646,471, both incorporated by reference. A height sensor using UV radiation instead of visible or infrared radiation is disclosed in US2010233600A1, incorporated by reference. In WO2016102127A1, incorporated by reference, a compact height sensor is described which uses a multi-element detector to detect and recognize the position of a grating image, without needing a detection grating.

Referring again to Equation (4), the height measurement values LS(x) (matrix LS) may correspond to measurements of the height of the substrate W obtained by the triangulation techniques described above in relation to the level sensor LS (where the measurements of the height may be determined by a height measurement calibration system ES in relation to a calibration substrate). The height measurement values S(x) (matrix S) may correspond to measurements of the height of the substrate W obtained by measurements of the intensity of radiation reflected by the substrate W, polarization filtered measurements, measurements obtained at different wavelengths, measurements obtained using modulated radiation, and/or any other kind of filtered measurement of the substrate height, as discussed above and in more detail below. It will be understood that the terms “calibration substrate height measurement values” and “production substrate height measurement values” as used herein may refer to height measurement values LS(x) and/or height measurement values S(x).

Once LS and S have been determined for a calibration substrate corresponding to a given type of production substrate, the calibration terms C can be determined by solving Equation (4) using multi variable regression, e.g. using a least square fit method. The number of locations on the substrate should be greater than the number of the plurality of calibration substrate height measurement values at each location, i.e. m>n. The larger the value of m, the better the fit will be.

LS and S are determined for one or more production substrates corresponding to the calibration substrate. It will be appreciated that LS and S may be determined before, after, or simultaneously with the determination of LS and S for the calibration substrate. LS and S may be determined for the production substrate in the same way as they were determined for the calibration substrate. The real wafer topography TOPO of each production substrate can then be determined by:

$$TOPO = L - C * S \qquad ( 5 )$$

In order to obtain the calibration substrate height measurement values and the production substrate height measurement values at a plurality of locations on the respective substrates W, the height measurement system LS, and/or the height measurement calibration system ES, comprises a movement mechanism operable to adjust the measurement location MLO (i.e. the location on the substrate W at which the beam of radiation BE1 is directed onto the substrate W) by moving the substrate support WT and/or the radiation source LSO. For example, the movement mechanism may comprise one or more actuators operable to move the support WT in the X-, Y-, and/or Z-direction, and/or one or more actuators operable to adjust an angle of the radiation source LSO and/or to move the radiation source LSO in the X-, Y-, and/or Z-direction. An example of a movement mechanism is the second positioner PW illustrated in FIG. 1.

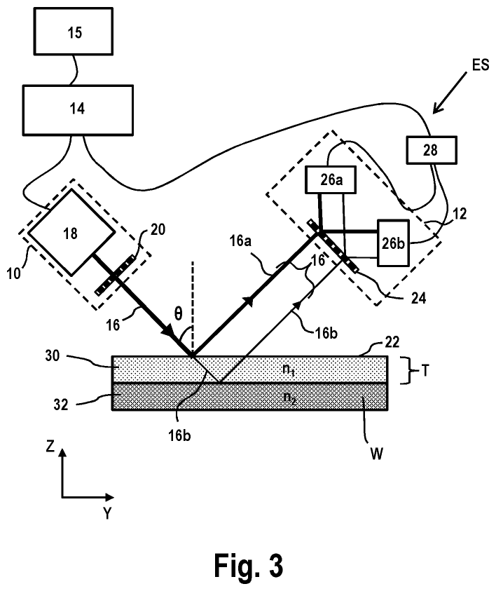

As discussed above, S may comprise substrate height measurement values corresponding to measurements obtained using modulated radiation. FIG. 3 illustrates an example of a height measurement calibration system ES in more detail. As noted above, some components of the height measurement calibration system ES may also form part of the height measurement system LS. In general, a projection unit 10 comprises a light source 18 and is configured to direct a beam of radiation 16 from the light source 18 onto an upper surface 22 of a substrate W (which substrate W may be a calibration substrate for the purposes of obtaining the calibration terms). The projection unit 10 may also include a diffraction grating 20. The diffraction grating 20, which is referred to as the projection grating 20 applies a periodic structure to the beam of radiation 16. The beam of radiation 16 subtends an acute angle θ with respect to a normal which extends from the substrate W (in other words, with respect to the Z-direction).

The example height measurement system ES illustrated in FIG. 3 may be particularly suitable for obtaining substrate height measurement values corresponding to measurements obtained using modulated radiation. The substrate height measurement values corresponding to measurements obtained using modulated radiation may correspond to the height measurement error (i.e. the HPD). While in the following description of FIG. 3 the light source 18 is a single-wavelength laser, it will be understood that other light sources may be employed in addition to, or instead of, the single-wavelength laser.

As shown in FIG. 3, a lock-in amplifier 14 is configured to modulate the wavelength of the laser beam that is emitted by the projection unit 10. The lock-in amplifier 14 is further configured to receive an output signal from the detection system 12. The detected position of the reflected laser beam is modulated due to the wavelength modulation of the laser beam. The lock-in amplifier 14 provides an output which is a measurement of the detected position modulation. The processor 15 uses the output from the lock-in amplifier to determine a height measurement error.

The laser 18 is configured to emit the laser beam 16 with a bandwidth of less than 2 nm, and may be referred to as a narrowband laser. The lock-in amplifier 14 applies a modulation to the wavelength of the laser beam 16 emitted by the laser 18. The modulation may for example vary the wavelength of the laser beam 16 by around 1 pm. The modulation may vary the wavelength of the laser beam by up to 10 pm, e.g. up to 50 pm. The modulation may vary the wavelength by more than this, for example up to 100 pm. However, if a larger wavelength modulation such as 100 pm is used, the output from the lock-in amplifier 14 may no longer be in a linear regime (this will depend upon the structure of the substrate).

In general, the modulation of the wavelength may be up to 1/100^{th} of a central wavelength of the laser beam 16.

In general, a substrate W will comprise many patterned layers. However, for simplicity of description, the substrate W depicted in FIG. 3 has only two layers, a lower layer of silicon 32 (which may be referred to as a ‘base’ substrate) and an upper layer of photoresist 30 (which may be referred to as resist). A main portion 16a of the laser beam 16 is reflected from an upper surface 22 of the resist 30. The reflected main portion of the laser beam 16a is reflected towards the detection system 12.

The detection system 12 comprises a diffraction grating 24 and a pair of detectors 26a,b. The diffraction grating 24 may be referred to as the detection grating 24. The reflected main portion of the laser beam 16a forms an image of the projection grating 20 at the detection grating 24. The detection grating 24 may have a periodicity which corresponds with a periodicity of a grating image formed by the reflected main portion of the laser beam 16a. The position of this grating image will depend upon the height of the upper surface 22 of the resist 30. The detection grating 24 directs laser light towards the first and second detectors 26a,b. The proportion of laser light received by each detector 26a,b depends upon the position of the grating image with respect to the detection grating 24. Thus, the signals output from the detectors 26a,b depend upon the height of the upper surface 22 of the resist 30. A differential amplifier 28 may be used to determine a difference between the signals output from the detectors 26a,b. An output from the differential amplifier 28 is provided to the lock-in amplifier 14. Other position detection systems for detecting the position of a reflected laser beam may be used.

The projection unit 10 and the detection system 12 may include further optical elements, such as lenses and/or mirrors (not depicted), along the path of the laser beam 16 (e.g. between the projection grating 20 and the detection grating 24).

As noted above, the main portion of the laser beam 16a is reflected from the upper surface 22 of the resist 30. However, the resist 30 is not a perfect reflector, and as a result a portion 16b of the laser beam 16 passes through the resist. This secondary laser beam portion 16b is reflected from an interface between the resist 30 and the silicon substrate 32. The secondary laser beam portion 16b is a relatively small proportion of the incident laser beam 16, for example 10% or less of the incident laser beam (e.g. 1% or less of the incident laser beam). This is schematically depicted by the secondary laser beam portion 16b being a line which is less thick than the main laser beam portion 16a.

The secondary laser beam portion 16b also forms an image of the projection grating 20 at the detector grating 24. However, this grating image is formed at a different, lower, position than the grating image formed by the main laser beam portion 16a. As can be seen from FIG. 3, the position of the detector grating image provided by the secondary laser beam portion 16b is determined by the height of the silicon substrate 32. A height offset between the position of the grating image provided by the main laser beam portion 16a and the position of the grating image provided by the secondary laser beam portion 16b will depend upon the thickness T of the resist.

The grating image formed by the secondary laser beam portion 16b introduces a measurement error into the signals output from the detectors 26a,b. The signals output from the detectors 26a,b will indicate that the height of the upper surface 22 of the resist is below the actual height of the upper surface of the resist. The height measurement calibration system ES determines this height measurement error.

The measurement obtained by the height measurement calibration system ES illustrated in FIG. 3 is now explained in more detail with reference to FIG. 3. The optical path difference L between the main laser beam portion 16a and the secondary laser beam portion 16b may be expressed as:

$$L ( θ ) = 2 T \sqrt{{n}_{1}^{2} - {sin}^{2} ( θ )} \qquad ( 6 )$$

The reflected laser beam 16 considered as a single beam has a complex amplitude:

$${E}_{r} = A + a exp ( - i 2 π \frac{L ( θ )}{λ} ) \qquad ( 7 )$$

where A is the amplitude of the main laser beam portion 16a and a is the amplitude of the secondary laser beam portion 16b. It can be assumed that n₁>>1 and n₁≈n₂ (n is the refractive index of the resist 30 and n₂ is the refractive index of the silicon substrate 32). Consequently, it can be assumed that the reflection 16b from the silicon substrate 32 is weak compared to the reflection 16a from the resist 30. When a<<A the phase of the reflected laser beam 16 is:

$$φ ( θ ) \approx \frac{a}{A} sin ( 2 π \frac{L ( θ )}{λ} ) \qquad ( 8 )$$

The height measurement error HPD caused by the secondary laser beam portion 16b, with an assumption that n²>>sin(θ), may be expressed as:

$$HPD = \frac{λ}{4 π sin ( θ )} \frac{d φ}{d θ} \approx \frac{T}{{n}_{2}} \frac{a}{A} cos ( 4 π \frac{{n}_{2} T}{λ} ) cos ( θ ) \qquad ( 9 )$$

Equation 9 includes the following term:

$$cos ( 4 π \frac{{n}_{2} T}{λ} ) \qquad ( 10 )$$

which indicates that the measurement error HPD will oscillate as a function of the wavelength of the laser beam 16. Embodiments of the disclosure obtain information regarding the height measurement error HPD by applying a modulation to the wavelength of the laser beam 16.

The lock-in amplifier 14 modulates a signal that controls operation of the laser 18 such that the wavelength of the laser beam 16 is modulated. The modulation is at a given frequency (e.g. selected by a user or automatically selected by the lock-in amplifier). This causes a modulation of the position of the reflected laser beam 16 as detected by the detectors 26a,b.

The lock-in amplifier 14 measures a modulation of the detected position of the laser beam 16 using the frequency of the modulation applied to the laser beam. The lock-in amplifier is configured to identify a harmonic (e.g. a first harmonic) of the signal output from the operational amplifier 28 (or other output signal if a different position detection system is used). The lock-in amplifier 14 identifies the harmonic as a component of the output signal which has a frequency which is a harmonic of the modulation applied to the laser 18. The lock-in amplifier 14 provides an output signal having an amplitude which indicates the amplitude of the detected harmonic. The processor 15 receives the output signal from the lock-in amplifier 14. The processor 15 uses the output signal to determine the height measurement error.

In some instances, the first harmonic of the signal received by the lock-in amplifier may have a lower amplitude than for example the second harmonic. The relative amplitudes of different harmonics will depend upon the refractive index and thickness of the layer of resist 30 in the scenario depicted in FIG. 3. The lock-in amplifier 14 may be configured to automatically select a harmonic which provides the greatest signal amplitude. In other scenarios (not depicted) in which the substrate is provided with more layers, the relative amplitudes of different harmonics will depend upon the refractive index and thickness of each layer. Again, the lock-in amplifier 14 may be configured to automatically select a harmonic which provides the greatest signal amplitude. For example, for some substrates the first harmonic may provide a strong signal that can be used to determine the height measurement error. For other substrates, the second harmonic may provide a strong signal that can be used to determine the height measurement error. Other harmonics may be used. In general, lock-in detection automatically selects between a first harmonic, second harmonic, or other harmonic of the frequency of the modulation based upon amplitudes of those harmonics.

In general, lock-in detection is used to measure a modulation of the detected position of the modulated wavelength laser beam (as detected by the detectors 28a,b). The lock-in detection is achieved by modulating the laser beam at a given frequency, and then using that frequency to identify the modulation of the detected position. The modulation of the laser beam, and the lock-in detection, may both be performed by the lock-in amplifier 14.

In an embodiment, a broadband light source (or other light source) of the height measurement system LS may be provided adjacent to the laser 18 of the height measurement calibration system ES. Where this is the case, the projection grating 20, detection grating 24, detector 26 may be common between the two systems. The systems LS, ES may operate simultaneously. That is, the height measurement system LS may measure a height map for a substrate W (which may correspond to the matrix LS), and the height measurement calibration system ES may at the same time determine a height measurement error (which may form part of the matrix S).

In the scenario depicted in FIG. 3, the adjustment that is determined may be an absolute measurement of the height measurement error HPD, i.e. a value which indicates an offset between the measured height of the upper surface 22 of the resist 30 and the actual height of the upper surface of the resist. Referring to Equation (10), the refractive index n₂ of the resist 30 is known, the angle of incidence θ of the laser beam 16 is known, and the wavelength λ of the laser beam is known. The relative amplitudes a, A of the first and second laser beam portions 16a,b may be measured during a calibration. The height measurement error HPD can therefore be treated as an absolute value which depends upon the only unknown T.

Typically, more than 200 dies are exposed on a substrate, and in some cases more than 600 dies are exposed on a substrate. Each of the dies has been exposed using the same series of patterning device exposures and has experienced the same processing. Thus, each of the dies should have the same properties, including the same height measurement error. In practice, the height measurement error may vary across a substrate. This may occur for example due to the effect of processing of substrate layers. In one example, metal may be deposited into structures formed in the substrate, and excess metal may be removed from the substrate using polishing. The polishing may for example remove slightly more material from one side of the substrate compared with an opposite side of the substrate (e.g. there may be a gradient of metal thickness across the substrate). Embodiments of the disclosure may provide as an output height measurement error values which vary gradually across the surface of a substrate.

Alternatively, or in addition, to values corresponding to measurements obtained using modulated radiation (i.e. height measurement error values), S may comprise measurements of the intensity of the radiation detected by the detection system 12. In some examples, S may comprise a polarization filtered measurement. For example, the height measurement system LS and/or the height measurement calibration system ES may comprise one or more polarizing filters located in the path of the beam of radiation BE1, BE2, 16, 16a, 16b. The polarizing filters may be controllable or selectable by a controller, which may include the processor 15. In some examples, S may comprise measurements obtained at different wavelengths. For example, the light source 18 may comprise multiple single wavelength light sources, and/or one or more gratings, prisms, and/or filters may be located in the path of the beam of radiation BE1, BE2, 16, 16a, 16b to enable wavelength selection. The wavelength may be selected by a controller, which may include the processor 15.

In order to cover the surface of the substrate W effectively, embodiments of the disclosure may be configured to project an array of laser beams 16 onto the surface of the substrate W. This provides an array of measurement areas on the substrate, covering a larger measurement range.

Described embodiments of the disclosure comprise a height measurement system LS and a separate height measurement calibration system ES. However, in an embodiment a single system may be used. That is, the height measurement calibration system ES may determine a height measurement error and may also provide a substrate height measurement.

Embodiments of the invention are described as comprising a single frequency laser having a bandwidth of 10 MHz or less, e.g. a bandwidth of around 1 MHz. Embodiments of the invention may comprise a single frequency laser having a bandwidth of up to 20 MHz. Such an embodiment may provide a useful height measurement error. However, the dynamic range of such an embodiment will be less than for a single frequency laser having a narrower bandwidth.

The theory behind the calibration techniques disclosed herein will now be described.

For a given substrate (e.g. wafer stack), the height measurement error, HPD, may have a wavelength dependency. This wavelength dependency is strongly substrate dependent, and cannot be easily predicted. In known methods of determining the topography of a substrate, a substrate height measurement is generally obtained using a weighted average of this wavelength dependency curve. Since the weighting is fixed, small changes in the substrate lead to small changes in the HPD curve, which in turn result in variations in the HPD (in particular interfield and intrafield HPD). In the methods according to the present disclosure, additional measurement signals (i.e. the S(x) values) are obtained. If the HPD curve varied randomly, there would be no correlation between these signals and the total HPD. However, on a typical substrate the HPD variations across a wafer (interfield and intrafield) are typically small. Therefore, the variations in the HPD curve are expected to be small, and the variations measured by the additional signals exhibit a correlation with the total HPD and so can be used to correct variations. The methods disclosed herein may therefore be particularly suitable for correcting HPD variations within a wafer, such as interfield and intrafield HPD, which advantageously are the types of HPD that have the largest impact on the focusing of the height measurement system.

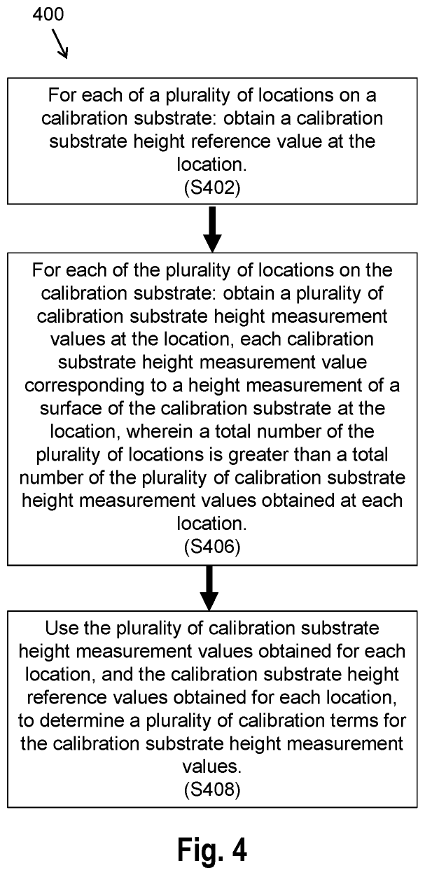

FIG. 4 illustrates an example of a method 400 for obtaining a calibration for a substrate topography measurement according to the present disclosure. For example, the method 400 may be performed by the processor 15 illustrated in FIG. 3, where the processor 15 may form part of a controller to control one or more elements of a height measurement system LS and/or a height measurement calibration system ES as described herein. Alternatively, or in addition, the method may be carried out with respect to a simulated calibration substrate, and one or more of the measurements of the method 400 may be simulated measurements.

In a step S402 of the method 400, for each of a plurality of locations (e.g. x₁, x₂, . . . , xₘ) on a calibration substrate, a calibration substrate height reference value (e.g. REF(x)) is obtained at the location.

In a step S406 of the method 400, for each of the plurality of locations on the calibration substrate, a plurality of substrate height measurement values (e.g. LS(x) and/or S₁(x), S₂(x), . . . , Sₙ(x)) is obtained at the location. Each calibration substrate height measurement value corresponds to a height measurement of a surface of the calibration substrate at the location. A total number of the plurality of locations should be greater than a total number of the plurality of calibration substrate height measurement values obtained at each location (i.e. m>n).

In a step S408 of the method 400, the plurality of calibration substrate height measurement values obtained for each location, and the calibration substrate height reference values obtained for each location, are used to determine a plurality of calibration terms (e.g. [C₀, C₁, C₂, . . . , Cₙ]) for the calibration substrate height measurement values. The plurality of calibration terms may be determined by multi variable regression.

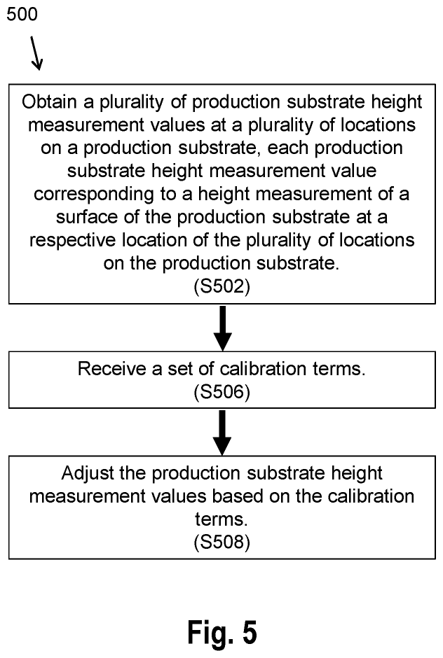

FIG. 5 illustrates an example of a method 500 for determining a topography of a production substrate. For example, the method 500 may be performed by the processor 15 illustrated in FIG. 3, where the processor 15 may form part of a controller to control one or more elements of a height measurement system LS and/or a height measurement calibration system ES as described herein.

In a step S502 of the method 500, a plurality of production substrate height measurement values is obtained at a plurality of locations on a production substrate. Each production substrate height measurement value corresponds to a height measurement of a surface of the production substrate at a respective location of the plurality of locations on the production substrate.

In a step S504 of the method 500, a set of calibration terms is received. The set of calibration terms may have been determined by the method 400 illustrated in FIG. 4, and/or using a substrate height calibration system ES. In some examples, the set of calibration terms may be stored in a memory and may be provided, e.g. to a processor 15, as an input (i.e. retrieved from the memory).

In a step S506 of the method 500, the production substrate height measurement values are adjusted based on the calibration terms. The adjusted production substrate height measurement values may provide a measurement of the substrate topography that is closer to the true substrate topography than may be achieved using known methods and techniques for reducing the height measurement error.

To demonstrate the effectiveness of the calibration techniques described in the present disclosure, the results of a simulated determination of the height measurement error (HPD) will now be presented and discussed. For the purposes of the simulation, a simulation of a real production substrate comprising a stack of 14 layers having different thicknesses was produced.

A Monte Carlo simulation was performed to calculate 100 different substrates having small variations according to the known tolerances of the thicknesses of the layers of the production substrate. The simulated heights of the substrates may be considered as the substrate height reference values, as described herein.

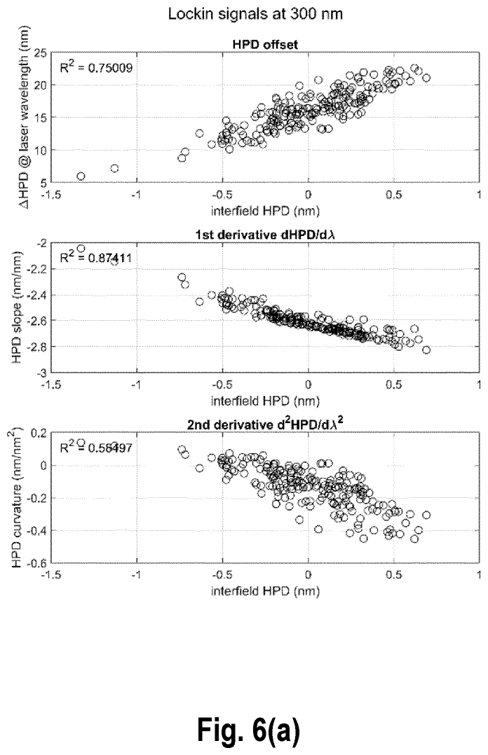

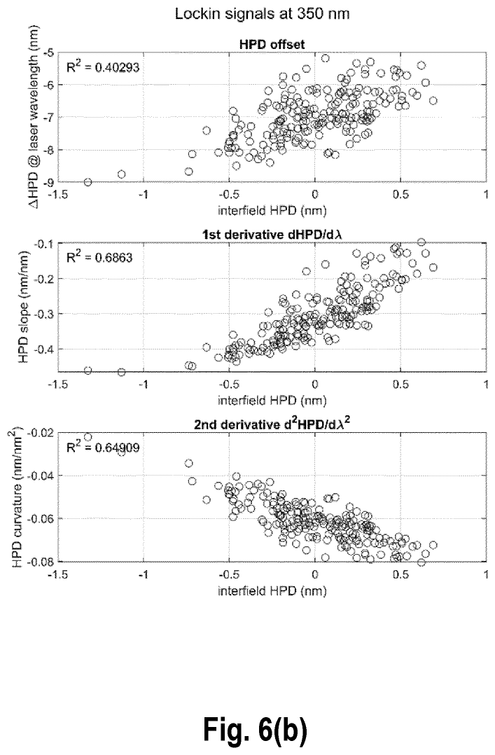

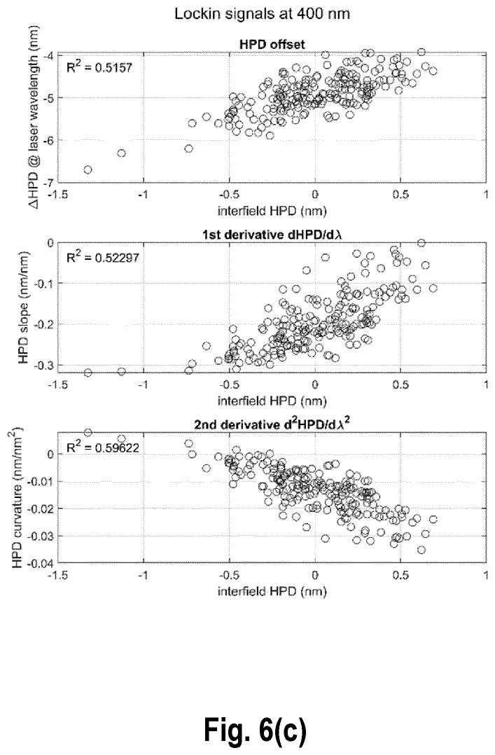

For each of the 100 simulated substrates, the height measurement value (signal) from the height measurement system LS was calculated, along with nine additional substrate height measurement values: at three different laser wavelengths (300 nm, 350 nm, and 400 nm), the substrate height measurement value (signal) corresponding to the height measurement error (as described above with reference to FIG. 3) was calculated, along with lock-in signals of the first harmonic (giving the local slope of the HPD curve) and the lock-in signals of the second harmonic (giving the local curvature of the HPD curve). The nine additional substrate height measurement values are plotted for the 100 simulated substrates in FIGS. 6(a)-(c), where the horizontal axes show the different calculated HPD values as the calculated heights of each substrate subtracted from the mean substrate height for the 100 substrates.

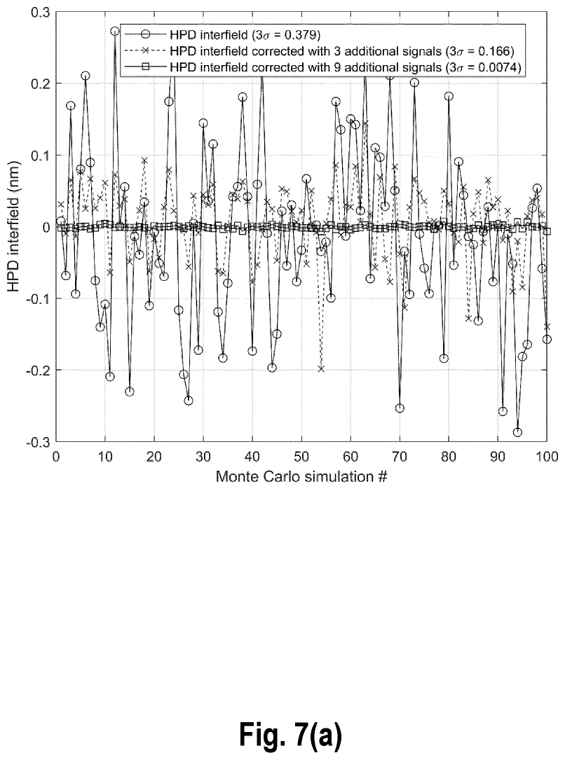

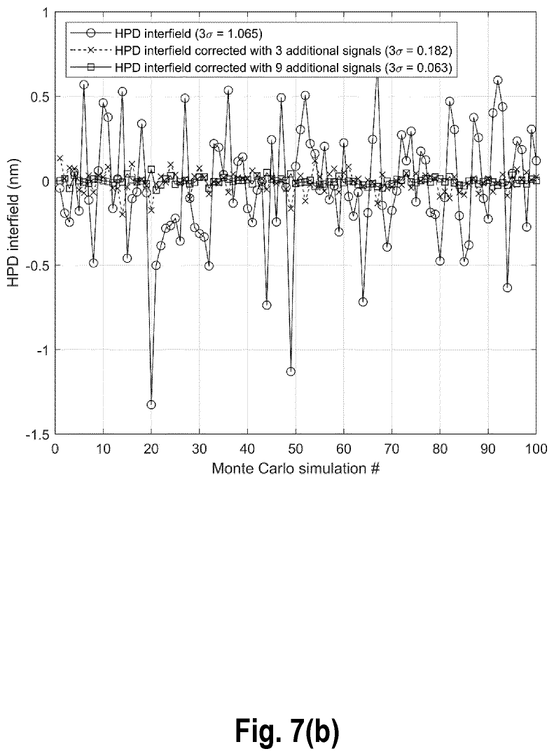

From the height measurement values, 10 calibration parameters were calculated. Next, a different set of 100 Monte Carlo simulations was used to calculate the HPD correction. FIG. 7(a) shows the variation in interfield HPD across the simulated substrates for a correction based only on the three substrate height measurement error signals (top plot of each of FIGS. 6(a)-(c); “three additional signals”), and based on all nine “additional signals” described above. When only the three substrate height measurement error signals were used in addition to the height measurement value from the height measurement system LS, a reduction in HPD of 83% was achieved. When the nine signals, including the first and second harmonics, were used, a reduction in HPD of 94% was achieved. FIG. 7(b) illustrates similar results of a second simulated substrate stack, in which a reduction in the HPD of 56% and 98% was achieved for the three and nine additional signals, respectively.

While the methods described herein have been described in relation to a substrate W that has, or will be, exposed to lithographic radiation (i.e. the radiation beam B), as will be clear to the skilled person, the methods (and corresponding apparatus) may beneficially be adapted for use with substrates that are not exposed to lithographic radiation.

In described embodiments of the invention, wavelength modulation and harmonic detection are performed by a lock-in amplifier. However, any suitable apparatus may be used to apply the wavelength modulation, and any suitable apparatus may be used to detect a harmonic of the applied modulation. In general, any of homodyne detection, heterodyne detection and quadrature detection may be used. These are examples of lock-in detection. Detection may use hardware or software.

The height measurement system and/or the height measurement calibration system may be referred to as an apparatus for obtaining a calibration for a substrate topography measurement, and/or an apparatus for determining a topography of a production substrate.

Embodiments of the disclosure may form part of a lithographic apparatus (e.g. as depicted). Embodiments of the disclosure may form part of a lithographic tool. Examples of lithographic tools are mentioned further below.

Likewise, while the methods described herein have been described in relation to DUV lithographic radiation, as will be clear to the skilled person, the methods (and corresponding apparatus) may be beneficially adapted for use with EUV lithographic radiation (and corresponding apparatus).

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the disclosure in the context of a lithographic apparatus, embodiments of the disclosure may be used in other apparatus. Embodiments of the disclosure may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the disclosure in the context of optical lithography, it will be appreciated that the disclosure, where the context allows, is not limited to optical lithography and may be used in other applications, for example imprint lithography, or in applications relating to optical distance measurement or optically profiling the surface of multi-layer materials.

Where the context allows, embodiments of the disclosure may be implemented in hardware, firmware, software, or any combination thereof. Embodiments of the disclosure may also be implemented as instructions stored on a machine-readable medium, which may be read and executed by one or more processors, for example processor 15, which may form part of a controller. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the disclosure have been described above, it will be appreciated that the disclosure may be practiced otherwise than as described. The descriptions above are intended to be illustrative, not limiting. Thus it will be apparent to one skilled in the art that modifications may be made to the disclosure as described without departing from the scope of the claims set out below. Other aspects of the invention are set out as in the following numbered clauses.
1. A method of obtaining a calibration for a substrate topography measurement, the method comprising:
for each of a plurality of locations on a calibration substrate:
obtaining a calibration substrate height reference value at the location; and
obtaining a plurality of calibration substrate height measurement values at the location, each calibration substrate height measurement value corresponding to a measurement of a surface of the calibration substrate at the location, wherein a total number of the plurality of locations is greater than a total number of the plurality of calibration substrate height measurement values obtained at each location;
the method further comprising:
using the plurality of calibration substrate height measurement values obtained for each location, and the calibration substrate height reference values obtained for each location, to determine a plurality of calibration terms for the calibration substrate height measurement values.
2. A method according to clause 1, comprising determining the plurality of calibration terms by means of multi variable regression.
3. A method according to clause 1 or 2, wherein the plurality of calibration substrate height measurement values comprises one or more values corresponding to an intensity measurement.
4. A method according to any one of the preceding clauses, wherein the plurality of calibration substrate height measurement values comprises one or more values corresponding to a polarization filtered measurement.
5. A method according to any one of the preceding clauses, wherein the plurality of calibration substrate height measurement values comprises values corresponding to measurements obtained at different measurement wavelengths.
6. A method according to any one of the preceding clauses, wherein the plurality of calibration substrate height measurement values comprises values corresponding to measurements obtained using modulated radiation.
7. A method according to any one of the preceding clauses, wherein one or more of the calibration substrate height reference values are simulated calibration substrate height reference values.
8. A method according to any one of the preceding clauses, wherein one or more of the calibration substrate height reference values are obtained by measurement of a height of the calibration substrate at the location.
9. A method according to any one of the preceding clauses, wherein one or more of the calibration substrate height measurement values are simulated calibration substrate height measurement values.
10. A method according to any one of the preceding clauses, wherein one or more of the calibration substrate height measurement values are obtained by a measurement of a height of the calibration substrate at the location.
11. A method of determining a topography of a production substrate, the method comprising:
obtaining a plurality of production substrate height measurement values at a plurality of locations on a production substrate, each production substrate height measurement value corresponding to a measurement of a surface of the production substrate at a respective location of the plurality of locations on the production substrate;
receiving a set of calibration terms obtained by a method according to any one of the preceding clauses; and
adjusting the production substrate height measurement values based on the calibration terms.
12. An apparatus for obtaining a calibration for a substrate topography measurement, the apparatus comprising:
   a support for supporting a calibration substrate;
a projection unit configured to direct a beam of radiation onto a location on the calibration substrate;
a movement mechanism operable to adjust the support and/or the projection unit so as to move the location on the calibration substrate at which the beam of radiation is directed onto the calibration substrate;
a detection system configured to detect the radiation after reflection by the location on the calibration substrate, the detection system further configured to determine a calibration substrate height measurement value corresponding to a measurement of a surface of the calibration substrate at the location; and
one or more controllers configured to operate the movement mechanism such that the beam of radiation is incident on a plurality of locations on the calibration substrate;
wherein the one or more controllers are further configured, for each of the plurality of locations on the calibration substrate, to:
receive a calibration substrate height reference value at the location; and
receive a plurality of calibration substrate height measurement values from the detection system, wherein a total number of the plurality of locations is greater than a total number of the plurality of calibration substrate height measurement values received at each location; and
wherein the one or more controllers are further configured to determine a plurality of calibration terms for the calibration substrate height measurement values using the plurality of calibration substrate height measurement values received for each location, and the calibration substrate height reference values received for each location.
13. An apparatus according to clause 12, wherein the controller is configured to determine the plurality of calibration terms by means of multiple variable regression.
14. An apparatus according to clause 12 or 13, wherein the detection system is configured to determine calibration substrate height measurement values corresponding to one or more of:
   an intensity measurement;
   a polarization filtered measurement;
   measurements obtained at different wavelengths;
   measurements obtained using modulated radiation.
15. An apparatus for determining a topography of a production substrate, the apparatus comprising:
a support for supporting a production substrate;
a projection unit configured to direct a beam of radiation onto a location on the production substrate;
a movement mechanism operable to adjust the support and/or the projection unit so as to move the location on the production substrate at which the beam of radiation is directed onto the production substrate;
a detection system configured to detect the radiation after reflection by the location on the production substrate, the detection system further configured to determine a production substrate height measurement value corresponding to a measurement of a surface of the production substrate at the location; and
one or more controllers configured to operate the movement mechanism such that the beam of radiation is incident on a plurality of locations on the production substrate;
wherein the one or more controllers are further configured, for each of the plurality of locations on the production substrate, to:
receive a plurality of production substrate height measurement values from the detection system;
receive a set of calibration terms obtained by a method according to any one of clauses 1 to 10; and
adjust the production substrate height measurement values based on the calibration terms.

1-15. (canceled)

16. A method of obtaining a calibration for a substrate topography measurement, for each of a plurality of locations on a calibration substrate the method comprising:
obtaining a calibration substrate height reference value at a location of the plurality of locations;
obtaining a plurality of calibration substrate height measurement values at the location, each calibration substrate height measurement value corresponding to a measurement of a surface of the calibration substrate at the location, wherein a total number of the plurality of locations is greater than a total number of the plurality of calibration substrate height measurement values obtained at each location; and
using the plurality of calibration substrate height measurement values and the calibration substrate height reference values obtained for each location to determine a plurality of calibration terms for the calibration substrate height measurement values.

17. The method of claim 16, further comprising determining the plurality of calibration terms using multi variable regression.

18. The method of claim 17, wherein the plurality of calibration substrate height measurement values comprises one or more values corresponding to an intensity measurement.

19. The method of claim 16, wherein the plurality of calibration substrate height measurement values comprises one or more values corresponding to a polarization filtered measurement.

20. The method of claim 16, wherein the plurality of calibration substrate height measurement values comprises values corresponding to measurements obtained at different measurement wavelengths.

21. The method of claim 16, wherein the plurality of calibration substrate height measurement values comprises values corresponding to measurements obtained using modulated radiation.

22. The method of claim 16, wherein one or more of the calibration substrate height reference values are simulated calibration substrate height reference values.

23. The method of claim 16, wherein one or more of the calibration substrate height reference values are obtained by measurement of a height of the calibration substrate at the location.

24. The method of claim 16, wherein one or more of the calibration substrate height measurement values are simulated calibration substrate height measurement values.

25. The method of claim 16, wherein one or more of the calibration substrate height measurement values are obtained by a measurement of a height of the calibration substrate at the location.

26. A method of determining a topography of a production substrate, the method comprising:
obtaining a plurality of production substrate height measurement values at a plurality of locations on a production substrate, each production substrate height measurement value corresponding to a measurement of a surface of the production substrate at a respective location of the plurality of locations on the production substrate;
receiving a set of calibration terms obtained by the method of claim 16; and
adjusting the production substrate height measurement values based on the calibration terms.

27. An apparatus configured to obtain a calibration for a substrate topography measurement, the apparatus comprising:
a support configured to support a calibration substrate;
a projection unit configured to direct a beam of radiation onto a location on the calibration substrate;
a movement mechanism operable to adjust the support and/or the projection unit to move the location on the calibration substrate at which the beam of radiation is directed onto the calibration substrate;
a detection system configured to detect the radiation after reflection by the location on the calibration substrate and configured to determine a calibration substrate height measurement value corresponding to a measurement of a surface of the calibration substrate at the location; and
one or more controllers configured to operate the movement mechanism such that the beam of radiation is incident on a plurality of locations on the calibration substrate and configured to, for each of the plurality of locations on the calibration substrate:
receive a calibration substrate height reference value at the location, and
receive a plurality of calibration substrate height measurement values from the detection system,
wherein a total number of the plurality of locations is greater than a total number of the plurality of calibration substrate height measurement values received at each location, and
wherein the one or more controllers are further configured to determine a plurality of calibration terms for the calibration substrate height measurement values using the plurality of calibration substrate height measurement values received for each location, and the calibration substrate height reference values received for each location.

28. The apparatus of claim 27, wherein the controller is configured to determine the plurality of calibration terms using multiple variable regression.

29. The apparatus of claim 27, wherein the detection system is further configured to determine calibration substrate height measurement values corresponding to one or more of:
an intensity measurement;
a polarization filtered measurement;
measurements obtained at different wavelengths; or
measurements obtained using modulated radiation.

30. An apparatus configured to determine a topography of a production substrate, the apparatus comprising:
a support configured to support a production substrate;
a projection unit configured to direct a beam of radiation onto a location on the production substrate;
a movement mechanism operable to adjust the support and/or the projection unit to move the location on the production substrate at which the beam of radiation is directed onto the production substrate;
a detection system configured to detect the radiation after reflection by the location on the production substrate and configured to determine a production substrate height measurement value corresponding to a measurement of a surface of the production substrate at the location; and
one or more controllers configured to operate the movement mechanism such that the beam of radiation is incident on a plurality of locations on the production substrate;
wherein the one or more controllers are further configured, for each of the plurality of locations on the production substrate, to:
receive a plurality of production substrate height measurement values from the detection system;
receive a set of calibration terms obtained by the method of claim 16; and
adjust the production substrate height measurement values based on the calibration terms.
